(19) United States
(12) Patent Application Publication
(10) Pub. No.: US 2012/0214293 A1
(43) Pub. Date: Aug. 23, 2012

(54) ELECTRODEPOSITING DOPED CIGS THIN FILMS FOR PHOTOVOLTAIC DEVICES

(76) Inventors: Serdar Aksu, San Jose, CA (US); Sarah Lastella, Mountain View, CA (US); Mustafa Pinarbasi, Morgan Hill, CA (US)

(21) Appl. No.: 13/153,310

(22) Filed: Jun. 3, 2011

Related U.S. Application Data
(63) Continuation-in-part of application No. 13/032,473, filed on Feb. 22, 2011.

(51) Int. Cl. H01L 21/368; C25D 3/56

(52) U.S. Cl. 438/478; 205/239; 257/E21.464

(57) ABSTRACT

Aspects of the present inventions include an electrodeposition solution for deposition of a thin film that includes a Group VA material, a method of electroplating to deposit a thin film that includes a Group VA material, among others.

### CLAIM OF PRIORITY

This application is a Continuation-in-Part of U.S. patent application Ser. No. 13/032,473, filed Feb. 22, 2011, entitled “ELECTROPLATING METHODS AND CHEMISTRIES FOR DEPOSITION OF COPPER-INDIUM-GALLIUM CONTAINING THIN FILMS, of which is expressly incorporated herein by reference.

### BACKGROUND

1. Field of the Inventions

The present invention is related to electrodeposition methods and electrodeposition solutions and, more particularly, to methods and electrodeposition solution chemistries for electrodepositing or co-electrodepositing dopant materials for Group IBIIIAVIA thin films for solar cells.

2. Description of the Related Art

Solar cells are photovoltaic (PV) devices that convert sunlight directly into electrical energy. Solar cells can be based on crystalline silicon or thin films of various semiconductor materials that are usually deposited on low-cost substrates, such as glass, plastic, or stainless steel.

Thin film based photovoltaic cells, such as amorphous silicon, cadmium telluride, copper indium diselenide or copper indium gallium diselenide based solar cells offer improved cost advantages by employing deposition techniques widely used in the thin film industry. Group IBIIIAVIA compound photovoltaic cells, including copper indium gallium diselenide (CIGS) based solar cells, have demonstrated the greatest potential for high performance, high efficiency, and low cost thin film PV products.

As illustrated in FIG. 1, a conventional Group IBIIIAVIA compound solar cell 10 can be built on a substrate 11 that can be a sheet of glass, a sheet of metal, an insulating foil or web, or a conductive foil or web. A contact layer 12 such as a molybdenum (Mo) film is deposited on the substrate as the back electrode of the solar cell. An absorber thin film 14 including a material in the family of Cu(In,Ga)(S,Se)₂ is formed on the conductive Mo film. The substrate 11 and the contact layer 12 form a base layer 13. Although there are other methods, Cu(In,Ga)(S,Se)₂ type compound thin films are typically formed by a two-stage process where the components (components being Cu, In, Ga, Se and S) of the Cu(In,Ga)(S,Se)₂ material are first deposited onto the substrate or a contact layer formed on the substrate as an absorber precursor, and are then reacted with S and/or Se in a high temperature annealing process.

After the absorber film 14 is formed, a transparent layer 15 including a buffer film such as CdS and a transparent conductive layer such as an undoped-ZnO/doped-ZnO stack, an undoped-ZnO/In—Sn—O (ITO) stack can be formed on the absorber film. In manufacturing the solar cell, the buffer layer is first deposited on the Group IBIIIAVIA absorber film 14 to form an active junction. Then the transparent conductive layer is deposited over the buffer layer to provide the needed lateral conductivity. Light enters the solar cell 10 through the transparent layer 15 in the direction of the arrows 16. The preferred electrical type of the absorber film is p-type, and the preferred electrical type of the transparent layer is n-type. However, an n-type absorber and a p-type window layer can also be formed. The above described conventional device structure is called a substrate-type structure. In the substrate-type structure light enters the device from the transparent layer side as shown in FIG. 1. A so called superstrate-type structure can also be formed by depositing a transparent conductive layer on a transparent superstrate, such as glass or transparent polymeric foil, and then depositing the Cu(In,Ga)(S,Se)₂ absorber film, and finally forming an ohmic contact to the device by a conductive layer. In the superstrate-type structure light enters the device from the transparent superstrate side.

Contrary to CIGS and amorphous silicon cells, which are fabricated on conductive substrates such as aluminum or stainless steel foils, standard silicon solar cells are not deposited or formed on a protective sheet. Such solar cells are separately manufactured, and the manufactured solar cells are electrically interconnected by a stringing or shingling process to form solar cell circuits. In the stringing or shingling process, the (+) terminal of one cell is typically electrically connected to the (−) terminal of the adjacent solar cell. Circuits may then be packaged in protective packages to form modules. Each module typically includes a plurality of strings of solar cells which are electrically connected to one another.

In a thin film solar cell employing a Group IBIIIAVIA compound absorber, the cell efficiency is a strong function of the molar ratio of IB/IIIA. If there are more than one Group IIIA materials in the composition, the relative amounts or molar ratios of these IIIA elements also affect the properties. For a Cu(In,Ga)(S,Se)₂ absorber layer, for example, the efficiency of the device is a function of the molar ratio of Cu/(In+Ga). Furthermore, some of the important parameters of the cell, such as its open circuit voltage, short circuit current and fill factor, vary with the molar ratio of the IIIA elements, i.e. the Ga/(Ga+In) molar ratio. In general, for good device performance the Cu/(In+Ga) molar ratio is kept at around or below 1.0. On the other hand, as the Ga/(Ga+In) molar ratio increases, the optical bandgap of the absorber layer increases and therefore the open circuit voltage of the solar cell increases while the short circuit current typically may decrease. It is important for a thin film deposition process to have the capability of controlling both the molar ratio of IB/IIIA, and the molar ratios of the Group IIIA components in the composition. The first technique that yielded high-quality Cu(In,Ga)Se₂ films for solar cell fabrication was co-evaporation of Cu, In, Ga and Se onto a heated substrate in a vacuum chamber. Another technique for growing Cu(In,Ga)(S,Se)₂ type compound thin films for solar cell applications is a two-stage process where at least two components of the Cu(In,Ga)(S,Se)₂ material are first deposited onto a substrate, and then reacted with S and/or Se in a high temperature annealing process. For example, for CuInSe₂ growth, thin layers of Cu and In may be first deposited on a substrate and then this stacked precursor layer may be reacted with Se at elevated temperature. If the reaction atmosphere also contains sulfur, then a CuIn(S,Se)₂ layer can be grown. Addition of Ga in the precursor layer, for example use of a Cu/In/Ga stacked film precursor, allows the growth of a Cu(In,Ga)(S,Se)₂ absorber.

Sputtering and evaporation techniques have been used in prior art approaches to deposit the layers containing the Group IB and Group IIIA components of the precursor stacks. In the case of CuInSe₂ growth, for example, Cu and In layers were sequentially sputter-deposited on a substrate and then the stacked film was heated in the presence of a gas containing Se at elevated temperature for times typically longer than about 30 minutes, as described in U.S. Pat. No. 4,798,660. More recently U.S. Pat. No. 6,048,442 disclosed a method comprising sputter-depositing a stacked precursor film comprising a Cu—Ga alloy layer and an In layer to form a Cu—Ga/In stack on a metallic back electrode layer and then reacting this precursor stack film with one of Se and S to form the absorber layer. Such techniques may yield good quality absorber layers and efficient solar cells, however, they suffer from the high cost of capital equipment, and relatively slow rate of production.

One prior art method described in U.S. Pat. No. 4,581,108 utilizes a low cost electrodeposition approach for metallic precursor preparation for a two-step processing technique. In this method a Cu layer is first electrodeposited on a substrate. This is then followed by electrodeposition of an In layer forming a Cu/In stack during the first stage of the process. In the second stage of the process, the electrodeposited Cu/In stack is heated in a reactive atmosphere containing Se forming a CuInSe₂ compound layer.

In another approach Cu—In or Cu—In—Ga alloys have been electroplated to form metallic precursor layers and then these precursor layers have been reacted with a Group VIA material to form CIGS type semiconductor layers. Some researchers electrodeposited all the components of the Group IBIIIAVIA compound layer. For example, for CIGS film growth electrolytes comprising Cu, In, Ga and Se were used. We will now review some of the work in this field.

Bonnet et al. (U.S. Pat. No. 5,275,714) electroplated Cu—In alloy layers out of acidic electrolytes that contained a suspension of fine Se particles. As described by Bonnet et al., this method yielded an electrodeposited Cu—In alloy layer which contained dispersed selenium particles since during electrodeposition of Cu and In, the Se particles near the surface of the cathode got physically trapped in the growing layer. Lokhande and Hodes (Solar Cells, vol. 21, 1987, p. 215) electroplated Cu—In alloy precursor layers for solar cell applications. Hodes et al. (Thin Solid Films, vol. 128, 1985, p. 93) electrodeposited Cu—In alloy films to react them with sulfur to form copper indium sulfide compound layers. They also experimented with an electrolyte containing Cu, In and S to form a Cu—In—S layer. Herrero and Ortega (Solar Energy Materials, vol. 20, 1990, p. 53) produced copper indium sulfide layers through H₂S-sulfidation of electroplated Cu—In films. Kumar et al (Semiconductor Science and Technology, vol. 6, 1991, p. 940, and also Solar Energy Materials and Solar Cells, vol.) formed a Cu—In/Se precursor stack by evaporating Se on top of an electroplated Cu—In film and then further processed the stack by rapid thermal annealing. Prosini et al (Thin Solid Films, vol. 288, 1996, p. 90, and also in Thin Solid Films, vol. 298, 1997, p. 191) electroplated Cu—In alloys out of electrolytes with a pH value of about 3.35-3.5. Ishizaki et al (Materials Transactions, JIM, vol. 40, 1999, p. 867) electroplated Cu—In alloy films and studied the effect of citric acid in the solution. Ganchev et al. (Thin Solid Films, vol. 511-512, 2006, p. 325, and also in Thin Solid Films, vol. 516, 2008, p. 5948) electrodeposited Cu—In—Ga alloy precursor layers out of electrolytes with pH values of around 5 and converted them into CIGS compound films by selenizing in a quartz tube.

Some researchers co-electrodeposited Cu, In and Se to form CIS or CuInSe₂ ternary compound layers. Others attempted to form CIGS or Cu(In,Ga)Se₂ quaternary compound layers by co-electroplating Cu, In, Ga and Se. Gallium addition in the quaternary layers was very challenging in the latter attempts. Singh et al (J. Phys. D: Appl. Phys., vol. 19, 1986, p. 1299) electrodeposited Cu—In—Se and determined that a low pH value of 1 was best for compositional control. Pottier and Maurin (J. Applied Electrochemistry, vol. 19, 1989, p. 361 electroplated Cu—In—Se ternary out of electrolytes with pH values between 1.5 and 4.5. Ganchev and Kochev (Solar Energy Matl. and Solar Cells, vol. 31, 1993, p. 163) carried out Cu—In—Se plating at a maximum pH value of 4.6. Kampman et al (Progress in Photovoltaics, vol. 7, 1999, p. 1999) described a CIS plating method. Other CIS and CIGS electrodeposition efforts include work by Bhattacharya et al (U.S. Pat. Nos. 5,730,852, 5,804,054, 5,871,630, 5,976,614, and 7297868), Jost et al (Solar Energy Matl. and Solar Cells, vol. 91, 2007, p. 636) and Kampmann et al (Thin Solid Films, vol. 361-362, 2000, p. 309).

In two-step deposition techniques, which involve deposition of a series of films to form a precursor film stack and then reaction of the precursor film stack to form the compound absorber. Individual thicknesses of the films that form the stacked precursor film layer must be well controlled because their thickness influence the final stoichiometry or composition of the compound layer after the reaction step. It has been known that when doped with Group IA alkali metals such as sodium (Na), potassium (K) and lithium (Li), the structural and electrical properties of CIGS absorbers are affected. Especially, incorporation of very small amounts of Na into CIGS layers has been shown to be beneficial for increasing the conversion efficiencies of solar cells fabricated using such layers. Doping CIGS layers with Na can be achieved by various ways. One popular method involves Na diffusion from glass substrates. Na diffuses into the CIGS layer from the substrate if the CIGS layer is grown on a Mo-contact layer deposited on a Na-containing soda-lime glass substrate. This is, however, an uncontrolled process and causes non-uniformities in the CIGS layers depending on how much Na diffuses from the substrate through the Mo-contact layer. In addition to alkali metals such as Na, K and Li, recent studies has shown that doping with antimony (Sb), which is a Group VA element, can also improve the CIGS absorber films. Although however the influence of Na incorporation on grain size and device performance has been extensively studied and reported in the literature, only a small amount of work is done for Group VA doping of CIGS-related systems. Recently, Min Yuan et al., (Optimization of CIGS-Based PV Device through Antimony Doping”, Chemistry of Materials, 2010, 22 (2), pp. 285-287) have reported highly desirable effects observed by Sb-doping in CIGS absorbers prepared by hydrazine-based spin coating approach.

From the foregoing, there is a need to develop doping techniques and electroplating baths to deposit smooth and defect-free doped Group IB-Group IIIA alloy or mixture films as well as doped Group IB-Group IIIA-Group VIA alloy or mixture layers in a repeatable manner with controlled composition.

### SUMMARY OF THE INVENTION

Aspects of the present inventions provides an electrodeposition solution for deposition of a thin film that includes a Group VA material, a method of electroplating to deposit a thin film that includes a Group VA material, among others.

In one aspect is described an electroplating solution for electroplating a Group VA thin film on a conductive surface, comprising: a solvent; a Group VA material dissolved in the solvent, the Group VA material including at least one of Sb, Bi and As; a Group IB material dissolved in the solvent, the Group IB material including Cu; a Group IIIA material dissolved in the solvent, the Group IIIA material including at least one of Ga and In; a first complexing agent forming a complex with the Group IB material; a second complexing agent forming a complex with the Group IIIA material; and a third complexing agent forming a complex with the Group VA material; wherein the pH of the solution is at least 7.0.

In another aspect is described a method of electroplating a thin film including a Group VA material on a conductive surface, comprising: providing an electrodeposition solution having a pH of at least 7 that includes therein a solvent, a Group VA material and another material, the another material including at least one of a Group IB material species, a Group IIIA material species, and a Group VIA material, and at least one complexing agent that complexes with the Group VA material and the another material to form soluble complex ions of the Group VA material and the another material: contacting the solution with an anode and the conductive surface; establishing a potential difference between the anode and the conductive surface; and electrodepositing the thin film including the Group VA material species and the another material on the conductive surface.

### BRIEF DESCRIPTION OF THE DRAWING

These and other aspects and features of the present invention will become apparent to those of ordinary skill in the art upon review of the following description of specific embodiments of the invention in conjunction with the accompanying figure, wherein:

FIG. 1 is a schematic view of a prior art solar cell structure; and

FIG. 2 is a schematic view of a precursor stack at an instant of the electrodepositon process forming the precursor stack

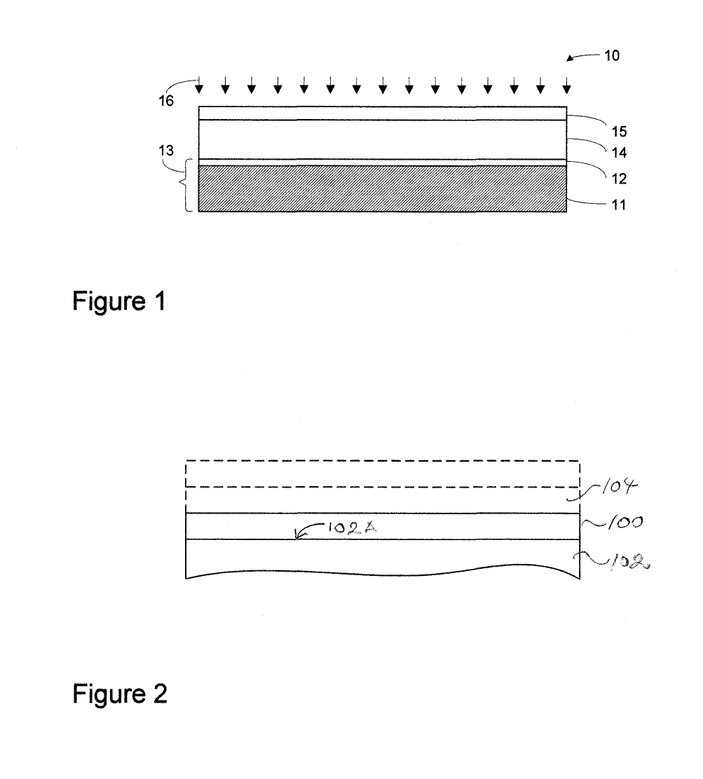

### DETAILED DESCRIPTION OF THE PREFERRED EMBODIMENTS

The present invention, in one embodiment provide methods and electroplating baths or electrolytes to co-electrodeposit (also called electrodeposit or electroplate or plate from now on) uniform, smooth and compositionally repeatable “Group IB-Group IIIA” alloy or mixture films where the Group IB material is Cu and the Group IIIA material is at least one of In and Ga. Such films include Cu—In, Cu—Ga and Cu—In—Ga alloy or mixture films. These embodiments also provide methods and electroplating baths or electrolytes to co-electrodeposit uniform, smooth and compositionally repeatable “Group IB-Group IIIA-Group VIA” alloy or mixture films where the Group IB material comprises Cu, the Group IIIA material comprises at least one of In and Ga and the Group VIA material comprises at least one of Se, Te and S. These films include layers of Cu(In,Ga)(S,Te,Se)₂. The stoichiometry or composition of such films, e.g. Group IB/Group IIIA atomic ratio, may be controlled by varying the appropriate plating conditions. Through the use of embodiments described herein it is possible to form micron or sub-micron thick alloy or mixture films on conductive contact layer surfaces for the formation of solar cell absorbers. As will be described below, in another embodiment, doped CIS and CIGS type solar cell absorbers may be prepared from precursors including Group VA elements as dopant elements, such as phosphorus (P), arsenic (As), antimony (Sb) and bismuth (Bi).

It should be noted that the prior art plating solutions for the above mentioned group of materials have an acidic pH range of <7. The embodiments described herein use a neutral (pH=7) to basic (pH>7) range for the pH of the solutions and employ at least one complexing agent to effectively complex one of Cu, In and Ga at this pH value. Present inventors recognized the benefits of such high pH ranges and use of specific complexing agents for the electrodeposition of Ga containing metallic layers (see for example, U.S. patent application Ser. No. 11/535,927, filed Sep. 27, 2006, entitled “Efficient Gallium Thin Film Electroplating Methods and Chemistries”), (In,Ga)—Se containing layers (see for example, U.S. patent application Ser. No. 12/123,372, filed May 19, 2008, entitled “Electroplating Methods and Chemistries for Deposition of Group IIIA-Group VIA thin films”) and Se layers (see for example, U.S. patent application Ser. No. 12/121,687, filed May 15, 2008, entitled “Selenium Electroplating Chemistries and Methods”), each of which are explicitly incorporated be reference herein. Various aspects of the present inventions will now be described.

1) Group IB-IIIA metallic layer deposition: In this embodiment the preferred electroplating bath comprises Cu, at least one Group IIIA (Ga and In) material, and a blend of at least two complexing agents that have the ability to complex with Cu and the Group IIIA species to keep them from precipitating in the non-acidic electrolyte which has a pH value of larger than or equal to 7. As is commonly known in the art of electrodeposition, complexing agents are soluble species that combine with metal ions in solution to form soluble complexes or complex ions. It should be noted that the acidic solutions of the prior art techniques may not have used such complexing agents since Group IIIA species typically remain in solution at acidic pH values. Although various complexing agents such as tartaric acid, citric acid, acetic acid, malonic acid, malic acid, succinic acid, ethylenediamine (EN), ethylenediaminetetra acetic acid (EDTA), nitrilotriacetic acid (NTA), and hydroxyethylethylenediaminetriacetic acid (HEDTA), etc. may be employed in the plating bath, the preferred complexing agents are tartaric acid or a tartrate, such as potassium sodium tartrate (KNaC₄H₄O₆) and citric acid or a citrate such as sodium citrate.

Copper in the electrolyte may be provided by a Cu source such as dissolved Cu metal or a Cu salt such as Cu-sulfate, Cu-chloride, Cu-acetate, Cu-nitrate, etc. The Group IIIA material source comprises at least one of dissolved In and Ga metals, and dissolved In and Ga salts, wherein the In salts may include In-chloride, In-sulfate, In-sulfamate, In-acetate, In-carbonate, In-nitrate, In-phosphate, In-oxide, In-perchlorate, and In-hydroxide, etc., and wherein the Ga salts may include Ga-chloride, Ga-sulfate, Ga-sulfamate, Ga-acetate, Ga-carbonate, Ga-nitrate, Ga-perchlorate, Ga-phosphate, Ga-oxide, and Ga-hydroxide, etc.

The preferred complexing agent for electrolytes used for Cu—Ga layer electroplating comprises citric acid or a citrate. The preferred complexing agent for electrolytes used for Cu—In film electroplating comprises tartaric acid or a tartrate. The preferred blend of complexing agents used for Cu—In—Ga film electroplating comprises both citrate and tartrate. Using such specific blend of complexing agents at the neutral and high pH ranges improves the plating efficiencies of these Group IB-IIIA materials. Citrates in the blend complex efficiently with the Ga species, tartrates in the blend complex efficiently with the In species. Both tartrates and citrates, on the other hand, complex well with Cu species. Therefore, in electrolytes comprising Cu and both In and Ga species, it is beneficial to include a blend of complexing agents comprising both tartrates (or tartaric acid) and citrates (or citric acid) to obtain high plating efficiencies and good compositional control, i.e. Cu/In, Cu/Ga, In/Ga, Cu/(In+Ga) molar ratios. It should be noted that other complexing agents may additionally be included in the solution formulation.

As stated above the solutions or electrolytes used in the embodiments herein preferably have pH values of 7 or higher. A more preferred pH range is above 9. These basic pH values are suitable for large scale manufacturing and provide good complexation for all of the Cu, In and Ga species in the electrolyte and bring their plating potentials close to each other for better repeatability and control of the plated alloy film compositions. It is for this reason that the Ga content of the Cu—In—Ga layers of the embodiments may be controlled at will in a range from 0% to 100%. This is unlike prior art plating solutions and methods which generally had difficulty to include appreciable amount of Ga in the electroplated layers due to excessive hydrogen generation due to high negative plating potential of Ga out of acidic electrolytes.

2) Group IB-IIIA-VIA layer deposition: In this embodiment the electroplating bath comprises Cu, at least one Group IIIA (Ga and In) material, at least one Group VIA material (Se, S and Te) and at least one complexing agent that has the ability to complex with Cu and the Group IIIA species to keep them from precipitating in the non-acidic electrolyte which has a pH value of larger than or equal to 7. A unique property of the relatively high pH electrolytes of the embodiments herein is the fact that Group VIA materials such as Se, S and Te are soluble in basic solutions, and therefore even if they do not complex well with the complexing agents, they do not form precipitates. Therefore, the neutral to alkali (or basic) pH values (pH values larger than or equal to about 7) of the plating chemistries have the ability to keep all of the Group IB, Group IIIA and Group VIA species in solution without precipitation. As explained above, the Group IB and Group IIIA species are believed to be kept in solution without precipitation through complexing with the complexing agent, and the Group VIA species are believed to be kept in solution without precipitation through chemical dissolution at the high pH values. In addition to keeping these two species in solution, the unique chemistry of the embodiments herein also brings their deposition potentials close to each other so that co-electroplating of ternary films of Cu—In—Se, Cu—In—S, Cu—Ga—Se, and Cu—Ga—S, or electroplating of quaternary and pentenary films of Cu—In—Ga—Se, Cu—In—Ga—S, Cu—In—S—Se, Cu—Ga—S—Se and Cu—In—Ga—Se—S may be performed in such neutral and high pH solutions.

A preferred embodiment uses a blend of at least two complexing agents in plating solutions used to electrodeposit Group IB-IIIA-VIA layer. The blend of the complexing agents is designed so that one complexing agent in the blend may complex well with one of the species (for example at least one of Cu, In, Ga species) in the plating solution, whereas another complexing agent in the blend may complex well with another species in the plating solution. The type and the concentration of the complexing agents in the blend are selected to optimize the complexation of the targeted species so that they do not form precipitates and their plating potentials are adjusted with respect to each other. For example, for electrodeposition of a Cu—In—Ga—Se films a blend of complexing agents comprising a tartrate and citrate is preferred because the tartrate complexes well with the In species and the citrate complexes well with the Ga species, allowing relatively independent optimization and control of their respective complexation and plating characteristics.

Although various complexing agents such as tartaric acid, citric acid, acetic acid, malonic acid, malic acid, succinic acid, ethylenediamine (EN), ethylenediaminetetra acetic acid (EDTA), nitrilotriacetic acid (NTA), and hydroxyethylethylenediaminetriacetic acid (HEDTA), etc. may be employed in the plating bath for deposition of ternary and higher order materials listed above, the preferred complexing agents are tartaric acid or a tartrate, such as potassium sodium tartrate (KNaC₄H₄O₆) and citric acid or a citrate such as sodium citrate, lithium citrate, ammonium citrate, potassium citrate, and an organically modified citrate.

Copper in the electrolyte may be provided by a Cu source such as dissolved Cu metal or a Cu salt such as Cu-sulfate, Cu-chloride, Cu-acetate, Cu-nitrate, etc. The Group IIIA material source may comprise at least one of dissolved In and Ga metals and dissolved In and Ga salts, wherein the In salts include In-chloride, In-sulfate, In-sulfamate, In-acetate, In-carbonate, In-nitrate, In-phosphate, In-oxide, In-perchlorate, and In-hydroxide, etc., and wherein the Ga salts include Ga-chloride, Ga-sulfate, Ga-sulfamate, Ga-acetate, Ga-carbonate, Ga-nitrate, Ga-perchlorate, Ga-phosphate, Ga-oxide, and Ga-hydroxide, etc. Group VIA material may be provided by at least one of a Se source, a S source and a Te source. The Group VIA material source may comprise at least one of dissolved elemental Se, Te and S, acids of Se, Te and S, and dissolved Se, Te and S compounds, wherein the Se, Te and S compounds include oxides, chlorides, sulfates, sulfides, nitrates, perchlorides and phosphates of Se, Te and S. Some of the preferred sources include but are not limited to selenous acid (also known as selenious acid) (H₂SeO₃), selenium dioxide (SeO₂), selenic acid (H₂SeO₄), selenium sulfides (Se₄S₄, SeS₂, Se₂S₆) sodium selenite (Na₂SeO₃), telluric acid (H₆TeO₆), tellurium dioxide (TeO₂), selenium sulfides (Se₄S₄, SeS₂, Se₂S₆), thiourea (CSN₂H₄), and sodium thiosulfate (Na₂S₂O₃).

The preferred complexing agent for the electrolytes used for electroplating Ga-containing layers, for example the Cu—Ga-Group VIA layers, such as Cu—Ga—Se, Cu—Ga—Te, Cu—Ga—S, Cu—Ga—S—Se, Cu—Ga—S—Te, Cu—Ga—Se—Te layers, comprises citric acid or a citrate. The preferred complexing agent for electrolytes used for electroplating In-containing layers, for example Cu—In—Se, Cu—In—S, Cu—In—Te, Cu—In—S—Se, Cu—In—S—Te, and Cu—In—Se—Te layers comprises tartaric acid or a tartrate. The preferred blend of complexing agents used for the electrolytes employed for electroplating both Ga and In containing layers such as Cu—In—Ga—Se, Cu—In—Ga—S, Cu—In—Ga—Te, Cu—In—Ga—S—Te, Cu—In—Ga—Se—Te and Cu—In—Ga—S—Se comprise both citrate and tartrate. Using such blend of complexing agents at the neutral and high pH ranges improves the plating efficiencies of these Group IB-IIIA-VIA materials, which may be in the form of alloys or mixtures. Citrates complex efficiently with Ga species and tartrates complex efficiently with In species. Both tartrates and citrates complex well with Cu species. Group VIA materials of Se, S and Te, on the other hand, dissolve in the high pH solutions. As a result, solutions with no precipitating species are obtained. In electrolytes comprising Cu and both In and Ga species, it is beneficial to include both tartrates (or tartaric acid) and citrates (or citric acid) to obtain high plating efficiencies and good compositional control, i.e. Cu/In, Cu/Ga, In/Ga, Cu/(In+Ga) molar ratios. It should be noted that a Cu—In—Ga—Se alloy refers to a Cu(In,Ga)Se₂ compound film, whereas a Cu—In—Ga—Se mixture may comprise elemental Cu, In, Ga and Se, Cu—In, Cu—Ga, In—Ga, Cu—Se, In—Se, Ga—Se etc. species.

Tartrate sources include potassium sodium tartrate, other tartrate salts and compounds such as tartaric acid and diethyl L-tartrate and tartrate compounds and salts can including alkaline and alkaline earth metallic salts, ammonium salts of tartrates and organically modified tartrates such as alkyl or dialkyl tartrates.

Although water is the preferred solvent in the formulation of the plating baths of the preferred embodiments, it should be appreciated that organic solvents may also be added in the formulation, partially or wholly replacing the water. Such organic solvents include but are not limited to alcohols, acetonitrile, propylene carbonate, formamide, dimethyl sulfoxide, glycerin etc.

Although the DC voltage/current was utilized during the electrochemical co-deposition processes in the preferred embodiments, it should be noted that pulsed or other variable voltage/current sources may also be used to obtain high plating efficiencies and high quality deposits. Also these different electrochemical methods may be contributed to control the Group IIIA/Group VIA molar ratio in the electroplated layers. The temperature of the electroplating baths may be in the range of 5-120° C. depending upon the nature of the solvent. The preferred bath temperature for water based formulation is in the range of 10-90° C.

The electroplating baths of the preferred embodiments may comprise additional ingredients. These include, but are not limited to, grain refiners, surfactants, dopants, other metallic or non-metallic elements etc. For example, organic additives such as surfactants, suppressors, levelers, accelerators etc. may be included in the formulation to refine its grain structure and surface roughness. Organic additives include but are not limited to polyalkylene glycol type polymers, propane sulfonic acids, coumarin, saccharin, furfural, acryonitrile, magenta dye, glue, SPS, starch, dextrose, and the like.

Although the preferred Group IB element in the preferred embodiments is Cu, other Group IB elements such as Ag may also be used in place of or in addition to Cu in the electrolytes.

Although the present inventions are described with respect to certain preferred embodiments, modifications thereto will be apparent to those skilled in the art.

Aspects and combinations of these inventions include:

An electrodeposition solution for deposition of a Group IB-IIIA thin film on a conductive surface, the electrodeposition solution comprising: a solvent; a Group IB material source that dissolves in the solvent and provides a Group IB material; a Group IIIA material source that dissolves in the solvent and provides a Group IIIA material; and a blend of at least two complexing agents, one of the at least two complexing agent forming a complex with the Group IB material and the other one of the at least two complexing agent forming a complex with the Group IIIA material; wherein the pH of the solution is at least 7.0.

Another aspect is the above solution wherein each one of the at least two complexing agents comprises at least one of a carboxylate functional group and an amine functional group.

Another aspect is the above solution wherein the Group IB material comprises Cu and the Group IIIA material is at least one of In and Ga.

Another aspect is the above solution wherein the Group IIIA material comprises In and Ga.

Another aspect is the above solution wherein the at least two complexing agents comprise a citrate and a tartrate.

Another aspect is the above solution wherein the at least two complexing agents comprise a citrate and a tartrate.

Another aspect is the above solution wherein the citrate is at least one of citric acid, an alkali metal salt of citric acid, alkali earth metal salt of citric acid, and an organically modified citrate.

Another aspect is the above solution wherein the alkali and alkali earth metal salts of citric acid comprise at least one of sodium citrate, lithium citrate, ammonium citrate, potassium citrate.

Another aspect is the above solution wherein the tartrate is at least one of tartaric acid, an alkali metal salt of tartaric acid, an alkali earth metal salt of tartaric acid, ammonium tartrate, tetraalkyl ammonium tartrate, alkyl tartrate, dialkyl tartrate, and organically modified tartrate.

Another aspect is the above solution wherein the alkali and alkali earth metal salts of tartaric acid comprise at least one of sodium tartrate, potassium tartrate, lithium tartrate, and potassium sodium tartrate.

Another aspect is the above solution wherein the Group IB material source comprises at least one of dissolved Cu metal and dissolved Cu salts, wherein the Cu salts include Cu-chloride, Cu-sulfate, Cu-acetate, Cu-nitrate, Cu-phosphate, and Cu-oxide, wherein the Group IIIA material source comprises at least one of dissolved In and Ga metals and dissolved In and Ga salts, wherein the In salts include In-chloride, In-sulfate, In-sulfamate, In-acetate, In-carbonate, In-nitrate, In-phosphate, In-oxide, In-perchlorate, and In-hydroxide, and wherein the Ga salts include Ga-chloride, Ga-sulfate, Ga-sulfamate, Ga-acetate, Ga-carbonate, Ga-nitrate, Ga-perchlorate, Ga-phosphate, Ga-oxide, and Ga-hydroxide.

Another aspect is the above solution wherein the solvent is water.

Another aspect is the above solution wherein the at least two complexing agents comprise at least one of an acid and an alkali metal salt of the acid, and wherein the acid comprises one of tartaric acid, citric acid, acetic acid, malonic acid, malic acid, succinic acid, ethylenediamine (EN), ethylenediaminetetra acetic acid (EDTA), nitrilotriacetic acid (NTA), and hydroxyethylethylenediaminetriacetic acid (HEDTA).

In a different aspect, there is an electrodeposition solution for deposition of a Group IB-IIIA-VIA thin film on a conductive surface, the electrodeposition solution comprising: a solvent; a Group IB material source that dissolves in the solvent and provides a Group IB material; a Group IIIA material source that dissolves in the solvent and provides a Group IIIA material; a Group VIA material source that dissolves in the solvent and provides a Group VIA material; an at least one complexing agent that complexes with the Group IB and Group IIIA materials;

wherein the pH of the solution is at least 7.

Another aspect is the above electrodeposition solution wherein the at least one complexing agent comprises a blend of two or more complexing agents.

Another aspect is the above electrodeposition solution wherein each one of the two or more complexing agents comprises at least one of a carboxylate functional group and an amine functional group.

Another aspect is the above electrodeposition solution wherein the Group IB material comprises Cu, the Group IIIA material is at least one of In and Ga, and the Group VIA material is at least one of Se, S and Te.

Another aspect is the above electrodeposition solution wherein the Cu source comprises at least one of dissolved Cu metal and dissolved Cu salts, wherein the Cu salts include Cu-chloride, Cu-sulfate, Cu-acetate, Cu-nitrate, Cu-phosphate, and Cu-oxide, wherein the Group IIIA material source comprises at least one of dissolved In and Ga metals and dissolved In and Ga salts, wherein the In salts include In-chloride, In-sulfate, In-sulfamate, In-acetate, In-carbonate, In-nitrate, In-phosphate, In-oxide, In-perchlorate, and In-hydroxide, and wherein the Ga salts include Ga-chloride, Ga-sulfate, Ga-sulfamate, Ga-acetate, Ga-carbonate, Ga-nitrate, Ga-perchlorate, Ga-phosphate, Ga-oxide, and Ga-hydroxide.

Another aspect is the above electrodeposition solution wherein the Group VIA material source comprises at least one of dissolved elemental Se, Te and S, and acids of Se, Te and S, and dissolved Se, Te and S compounds, wherein the Se, Te and S compounds include oxides, chlorides, sulfates, sulfides, nitrates, perchlorides and phosphates of Se, Te and S.

Another aspect is the above electrodeposition solution wherein the Group IIIA material comprises both In and Ga and the blend of two or more complexing agents comprise a tartrate and a citrate.

Another aspect is the above electrodeposition solution wherein the tartrate comprises at least one of tartaric acid, an alkali metal salt of tartaric acid, an alkali earth metal salt of tartaric acid, ammonium tartrate, tetraalkyl ammonium tartrate, alkyl tartrate, dialkyl tartrate, and organically modified tartrate, and wherein the citrate comprises at least one of citric acid, an alkali metal salt of citric acid, alkali earth metal salt of citric acid, and an organically modified citrate.

Electrodeposition is an effective way to prepare absorber precursors doped with Group VA elements due to its low cost, efficient utilization of raw materials and scalability to high-volume manufacturing. Solar cells using Group IBIIIAVIA absorber films doped with Group VA materials tend to exhibit higher cell efficiencies than the solar cells doped solely with conventional doping materials such as Na. In the following embodiment of the present invention, doped CIS and CIGS type solar cell absorbers may be prepared from precursors including Group VA elements as dopant elements, such as phosphorus (P), arsenic (As), antimony (Sb) and bismuth (Bi). Precursor films including such Group VA elements may be co-electrodeposited with Group IB, Group IIIA and Group VIA elements such as copper, gallium indium or selenium as well as they may be electrodeposited as pure layers. If necessary a Se layer to add more Se as well as a Na dopant layer to add more dopants can be added using conventional evaporation techniques. As will be described below. Group VA materials may be electrodeposited as pure films or mixed alloy films including more than two elements such as binary, ternary, quaternary, quinary, and so on alloys of a Group VA material with the Cu, In, Ga and Se, and/or additional equivalent Group IB, Group IIIA and Group VIA materials. Alternately, substantially pure films of Group VA elements may be included in a precursor stack that includes electrodeposited Cu, In, Ga and Se films before reacting the stack to form a CIGS precursor. When electrodepositing a CIGS precursor, the Group VA elements may also be used to control the pre-alloying mechanism of the depositing CIGS layer(s) prior to the reaction step. For instance, the Group VA elements can induce a ternary alloy among Cu, In and a Group VA element that prevents copper and indium from diffusing through the precursor stack layer(s) before the subsequent reaction process step. In addition, the Group VA elements can also be used to prevent pre-alloying of copper, indium, gallium and/or selenium in the as deposited precursor by preferentially binding to one or more of these elements. By controlling the pre-alloying this way, the intended Cu, In, Ga, and Se composition/grading can be achieved and stabilized in the electroplated precursor.

In one embodiment, one or more substantially pure films of one of the Group V elements, such as Sb, Bi and As, may be added to CIGS or CIS precursor stacks trough electroplating of such pure films from singular baths of either Sb, Bi or As. In the context of this application, substantially pure film refers to a film made of a material in 95-99.99% purity. Phosphorus (P), on the other hand, may not be electrodeposited alone. P may preferably be co-electrodeposited with one of the materials of the CIGS such as copper. Precursor stacks containing these elements along with Cu, In, Ga and Se may be prepared using an electrodeposition process. Then, this precursor can be reacted in the second stage for preparation of the CIS or CIGS-type absorber. The invention can help achieving higher cell efficiencies by using electroplated Group VA elements as dopants.

In another embodiment, binary alloy films including Group VA elements are electrodeposited from electrodeposition solutions that includes one of the Group VA element such as Sb, Bi, As or P and Sb and one of the Cu, In, Ga or Se elements. For example Cu—Sb, In—Sb, Ga—Sb and Se—Sb binary alloy films may be electrodeposited from binary electrodeposition solutions including Cu and Sb, In and Sb, Ga and Sb and Se and Sb respectively. Similarly, Cu—Bi, In—Bi, Ga—Bi and Se—Bi binary alloy films may be electrodeposited from binary electrodeposition solutions including Cu and Bi, In and Bi, Ga and Bi, and Se and Bi respectively. Further similarly, Cu—As, In—As, Ga—As and Se—As binary alloy films may be electrodeposited from binary electrodeposition solutions including Cu and As, In and As, Ga and As, and Se and As respectively; and Cu—P, In—P, Ga—P and Se—P binary alloy films may be electrodeposited from binary electrodeposition solutions including Cu and P, In and P, Ga and P, and Se and P respectively. Due to their relative simplicity, these binary compositions may provide better bath compositional control that affects the compositional and morphological uniformity of the resulting film. In addition, it has been observed that it is generally easier to control Group VA element distribution, i.e.; dopant distribution in the binary alloy films.

In another embodiment, ternary alloy films including Group VA elements are electrodeposited from electrodeposition solutions that includes one of the Group VA elements such as Sb, Bi, As or P and Sb and two of the Cu, In, Ga or Se elements. For example Cu—Ga—Sb, Cu—In—Sb, In—Ga—Sb and Cu—Se—Sb ternary alloy films may be electrodeposited from ternary electrodeposition solutions including Cu, Ga and Sb, Cu, In and Sb, In, Ga and Sb and Cu, Se and Sb respectively. Similarly, Cu—Ga—Bi, Cu—In—Bi, In—Ga—Bi and Cu—Se—Bi ternary alloy films may be electrodeposited from ternary electrodeposition solutions including Cu, Ga and Bi, Cu, In and Bi, In, Ga and Bi and Cu, Se and Bi respectively. Further similarly, Cu—Ga—As, Cu—In—As, In—Ga—As and Cu—Se—As ternary alloy films may be electrodeposited from ternary electrodeposition solutions including Cu, Ga and As, Cu, In and As, In, Ga and As and Cu, Se and As respectively; and Cu—Ga—P, Cu—In—P, In—Ga—P and Cu—Se—P ternary alloy films may be electrodeposited from ternary electrodeposition solutions including Cu, Ga and P, Cu, In and P, In, Ga and P and Cu, Se and P respectively. The amount of Group VA element of dopant required in the final film can be adjusted by adjusting the complexation and concentration of the Group VA dopant elements. In another aspect of the present invention, for ternary and quaternary films, both Sb and Bi may be included together as dopants in the same precursor and may be deposited from electrodeposition solution including Sb, Bi and one or two of Cu, In, Ga and Se. For binary films both Sb and Bi may be electrodeposited together as a dopant film from binary electrodeposition solutions including Sb and Bi. Se can be included in the baths and its composition and plating potential can be separately controlled. In addition to Se, other Group VI elements source materials such acids and oxides of Te might also be introduced in plating bath to produce precursors and absorbers with desirable electronic and microstructural properties.

In another embodiment, quaternary alloy films including Group VA elements are electrodeposited from electrodeposition solutions that includes one of the Group VA element such as Sb, Bi, As or P and Sb and three of Cu, In, Ga or Se elements. For example Cu—In—Ga—Sb, Cu—In—Se—Sb quaternary alloy films may be electrodeposited from quaternary electrodeposition solutions including Cu, In, Ga and Sb, Cu, In, Se and Sb. Similarly, other quaternary alloy films may be formed by replacing the exemplary Sb with other Group VA elements such as Bi, As and P in the above exemplified quaternary electrodeposition solutions. Similarly, in another embodiment, quinary alloy films including Group VA elements are electrodeposited from electrodeposition solutions that includes one of the Group VA element such as Sb, Bi, As or P and Sb and four of Cu, In, Ga or Se elements. For example a Cu—In—Ga—Se—Sb quinary alloy film may be electrodeposited from a quinary electrodeposition solution including Cu, In, Ga, Se and Sb. Similarly, other quinary alloy films may be formed by replacing the examplary Sb with other Group VA elements such as Bi, As and P in the above exemplified quinary electrodeposition solution. In another aspect of the present invention, for ternary, quaternary and quinary films, both Sb and Bi may be included together as dopants in the same precursor and may be deposited from electrodeposition solution including Sb, Bi and two, three or four of Cu, In, Ga and Se.

FIG. 2 illustrates an examplary electroplating process to electroplate a thin film 100 including one or more Group VA dopant elements using one of the electrodeposition solutions described above. As shown, in principal, the film 100 may be electrodeposited on a surface 102A of a conductive layer 102. The conductive layer 102 may include a single conductive film or a stack of multiple conductive films. The conductive layer 102 may be a base layer of a solar cell including a solar cell substrate and an ohmic contact layer deposited on the substrate. Further, the conductive layer 102 may be one of a Cu layer, In layer, Ga layer and Se layer or their various possible combinations thereof. Similarly, another layer 104 or more layers comprised of one or more films may be electrodeposited on the film 100. The layer 104 may be one of a Cu layer, In layer, Ga layer, Se layer, and another Group VA dopant layer or their various possible combinations thereof.

In one embodiment, the following electroplating solution components may be used for the various alloy compositions including Group VA elements that are described above. The electrodeposition solution first includes a solvent such as DI water, a Group VA material source or dissolved Group VA ions, for example Sb, Bi, As or P ions. Depending on the desired alloy combination, the electrodeposition solution may further includes a copper source, an indium source, a gallium source, a selenium source or other group VIA element sources such as Te, one or more complexing agents for complexing Cu, Ga, In and Se elements, and one or more complexing agents for complexing Group VA materials. A pH of the solution may be greater than 7, preferably in the range of 9 to 14. Depending on the desired alloy composition, one complexing agent, multiple complexing agents or a blend of complexing agents may be used to complex dissolved In Ga and Cu, and optionally Se, ions and bring their plating potentials to the appropriate levels required. A mix of tartrate and citrate may be used as a complexing agent blend for one or more of Cu, In, Ga and Se. In this respect, tartaric acid and alkali tartrate salts could be used as the tartrate source; and citric acid and alkali citrate salts could be used as citrate source.

For Group VA dopant elements, one more complexing agents or their blends may be used for complexing dissolved Group VA material ions. For example for Sb and Bi, complexing agents can be selected from the group of chelating agents containing functional groups such as carboxylic acid or amine. Suitable complexing agents may also include ethylenediaminetetraacetic acid (EDTA), maleic acid, gluconic acid, acetic acid, oxalic acid, ethylenediamine, tartaric acid, triethanolamine, citric acid, and glycine, and the like. An examplary copper source may be example copper salts such as copper sulfate, copper chloride, copper oxide. An indium source may be indium salts such as indium sulfate, indium chloride, indium oxide. A gallium source may be gallium salts such as gallium sulfate, gallium chloride, gallium oxide. A selenium source may be selenium oxide or acids of selenium such as selenious acid. In addition to Se, other Group VI elements source materials such acids and oxides of Te might also be introduced in plating bath to produce precursors and absorbers with desirable electronic and microstructural properties. The generic bath composition given above can be tailored to produce specific baths for desired alloy films.

In addition to major constituents described above, it might be advantageous to include organic ingredients in electrolytes to refine the grains, improve the adhesion, provide leveling, reduce surface tension and minimize corrosion and pitting of molybdenum layer or stainless steel substrate. Major part of these organic ingredients are alcohols (up to 15% of the total electrolyte volume), either in the form of simple alcohols such as ethanol, methanol and isopropyl alcohol or as multihdydric alcohols, such as glycerol, which are believed to be helpful in minimizing the pitting and corrosion issues. In order to further inhibit corrosion behavior triazole-based inhibitors such as benzotriazole can be added in the solutions. Other common additives include polyalkylene glycol type polymers, sulfonic acids (especially in the form of propane sulfonic acids), thiourea, coumarin, saccharin, dextrose as well as some proprietary organic amine compounds. The pH of the solution in the alkaline regime can be adjusted by addition of sodium hydroxide, potassium hydroxide or ammonium hydroxide. Alkaline buffer couples could be also employed to adjust the pH. Suitable alkaline pH buffer systems include to monopotassium phosphate/dipotassium phosphate, boric acid/sodium hydroxide, sodium bicarbonate/sodium carbonate, monosodium tellurate/disodium tellurate, monosodium ascorbate/disodium ascorbate, and dipotassium phosphate/tripotassium phosphate. Conductivity of the electrolytes can be increased by addition of salts, preferably in the form of ammonium nitrate. As described above, although Sb and Bi are the preferred materials for this invention, P and As may also be used as dopants. Small amounts of phosphorous can be co-electrodeposited with copper, gallium indium or selenium from specialized baths as described above although the incorporation of P might be more challenging than Bi and Sb. Because of its toxicity, arsenic should be handled with care. However, if needed, As-doping can be achieved in a similar fashion to Sb and Bi-doping outlined above. Using the electrodeposition doping process of the present invention, smooth, defect-free, high quality sub-micron alloy thin films are produced for CIGS thin films doped with for example Bi and Sb.

### Example 1

A bismuth containing solution was prepared with 0.5 M sodium gluconate and 0.1 M bismuth triacetate. The pH was adjusted to 13 with sodium hydroxide. Bismuth was plated on an electroplated copper layer at 3 mA/cm² to achieve a bismuth film thickness of 2 to 20 nm. A Cu—In layer was plated on top of the bismuth film to form a Cu—In—Bi alloy. The rest of the CIGS precursor was deposited on top of this alloyed material. The pre-formed alloy prevented indium from freely diffusing through the thick precursor layer. When the same precursor is prepared without the bismuth layer, crystallized indium fingers can be detected breaking through the surface of the precursor using a scanning electron microscope.

### Example 2

A Cu—Bi layer could be plated with 5% or less Bi. This solution could contain 0.1 M copper sulfate and 0.01 M bismuth from bismuth acetate, bismuth chloride, bismuth oxide, etc. An In—Bi solution can be prepared using 0.1 M indium chloride, 0.01 M bismuth from bismuth acetate, bismuth chloride, bismuth oxide, etc. and tartaric acid. A Ga—Bi binary film can also be plated from a 0.1 M gallium chloride, 0.01M bismuth solution using bismuth acetate, bismuth chloride, bismuth oxide, etc.

### Example 3

A Cu—In—Bi, Cu—Ga—Bi, or In—Ga—Bi solution can be prepared with 0.01 M bismuth and 0.1 M copper sulfate, 0.1 M indium chloride, and/or 0.1 M gallium chloride. The bismuth salt can be acetate, chloride, oxide, etc.

In any of these examples, bismuth can be replaced with antimony by using antimony salts soluble at a pH above 7, such as KSb(OH)₆. Alternately, the bath can be formulated to include both Sb and Bi soluble salts to electrodeposit layers doped with both Sb and Bi.

In any of these examples, bismuth can also be replaced with arsenic by using As salts soluble at a pH above 7. Alternately, the bath can be formulated to include both As and Bi soluble salts to electrodeposit layers doped with both As and Bi. Alternatively, the bath can be formulated to include As, Sb and Bi soluble salts to electrodeposit layers doped with As, Sb and Bi.

Selenium can be added to any of the above mentioned solutions in the form of selenious acid, selenious oxide, sodium selenite etc., at 0.1M to plate a bismuth doped CIGS precursor. The pH of the bismuth containing solutions should be above 7 and is preferred to be between 9 and 14. It is preferred that the bismuth composition of any plated film does not exceed 5%. Similarly, the pH of the electrolytes containing other Group VA elements should be above 7 and is preferred to be between 9 and 14. It is that the Group VA composition of any plated film does not exceed 5%.

Although the present inventions have been particularly described with reference to embodiments thereof, it should be readily apparent to those of ordinary skill in the art that various changes, modifications and substitutes are intended within the form and details thereof, without departing from the spirit and scope of the invention. Accordingly, it will be appreciated that in numerous instances some features of the invention will be employed without a corresponding use of other features. Further, those skilled in the art will understand that variations can be made in the number and arrangement of components illustrated in the above figures. It is intended that the scope of the appended claims include such changes and modifications.

We claim:

1. An electroplating solution for electroplating a Group VAIBIIIA thin film on a conductive surface, comprising:
a solvent;
a Group VA material dissolved in the solvent, the Group VA material including at least one of Sb, Bi and As;
a Group IB material dissolved in the solvent, the Group IB material including Cu;
a Group IIIA material dissolved in the solvent, the Group IIIA material including at least one of Ga and In;
a first complexing agent forming a complex with the Group IB material;
a second complexing agent forming a complex with the Group IIIA material; and
a third complexing agent forming a complex with the Group VA material; wherein the pH of the solution is at least 7.0.

2. The solution of claim 1 further comprising a Group VIA material dissolved in the solvent, the Group VIA material including Se, Te and S so that the solution is for electroplating a Group VAIBIIIAVIA thin film on the conductive surface.

3. The solution of claim 1 wherein the solvent is water.

4. The solution of claim 1 wherein the first, second and third complexing agents each comprise at least one of a carboxylate functional group and an amine functional group.

5. The solution of claim 4 wherein at least one of the first, second and third complexing agents comprise at least one of an acid and an alkali metal salt of the acid, and wherein the acid comprises one of tartaric acid, citric acid, acetic acid, malonic acid, malic acid, succinic acid, gluconic acid, ethylenediaminetetra acetic acid, nitrilotriacetic acid, and hydroxyethylethylenediaminetriacetic acid.

6. The solution of claim 1, wherein the Group IB material is obtained from a Group IB material source comprising at least one of dissolved copper (Cu) metal and dissolved copper salts, wherein the copper salts include copper-chloride, copper-sulfate, copper-acetate, copper-nitrate, copper-phosphate, and copper-oxide, wherein the Group IIIA material is obtained from a Group IIIA material source comprising at least one of dissolved indium (In) and gallium (Ga) metals and dissolved indium and gallium salts, wherein the indium salts include indium-chloride, indium-sulfate, indium-sulfamate, indium-acetate, indium-carbonate, indium-nitrate, indium-phosphate, indium-oxide, indium-perchlorate, and indium-hydroxide, and wherein the gallium salts include gallium-chloride, gallium-sulfate, gallium-sulfamate, gallium-acetate, gallium-carbonate, gallium-nitrate, gallium-perchlorate, gallium-phosphate, gallium-oxide, and gallium-hydroxide, wherein the Group VA material is obtained from a Group VA material source comprising at least one of dissolved bismuth (Bi), antimony (Sb), and arsenic (As) and dissolved bismuth salts wherein the bismuth salts include bismuth-oxide, bismuth-chloride, bismuth citrate, and bismuth-acetate, and antimony salts wherein the antimony salts include antimony hydroxide, antimony oxide, antimony sulfide, antimony fluoride, antimony iodide, antimony bromide, and antimony chloride, and dissolved arsenic salts wherein the arsenic salts include arsenic fluoride, arsenic bromide, arsenic iodide, arsenic oxide, and arsenic sulfide.

7. The solution of claim 2 wherein the Group VIA material is obtained from a Group VIA material source comprising at least one of dissolved elemental selenium (Se), tellurium (Te) and sulfur (S), and acids of selenium (Se), tellurium (Te) and sulfur (S), and dissolved selenium (Se), tellurium (Te) and sulfur (S) compounds, wherein the selenium (Se), tellurium (Te) and sulfur (S) compounds include oxides, chlorides, sulfates, sulfides, nitrates, perchlorides and phosphates of selenium (Se), tellurium (Te) and sulfur (S).

8. The solution of claim 1 wherein the Group VA material includes Sb.

9. The solution of claim 1 wherein the Group VA material includes Bi.

10. The solution of claim 1 wherein the Group VA material includes As.

11. A method of electroplating a thin film including a Group VA material on a conductive surface, comprising:
providing an electrodeposition solution having a pH of at least 7 that includes therein a solvent, a Group VA material and another material, the another material including at least one of a Group IB material, a Group IIIA material, and a Group VIA material, and at least one complexing agent that complexes with the Group VA material and the another material to form soluble complex ions of the Group VA material and the another material:
contacting the solution with an anode and the conductive surface;
establishing a potential difference between the anode and the conductive surface; and
electrodepositing the thin film including the Group VA material and the another material on the conductive surface.

12. The method of claim 11, wherein the ratio of the molar concentration of Group VA elements to the sum of molar concentrations of Group IB and Group IIIA elements (VA/(IB+IIIA)) is up to 0.05.

13. The method of claim 11 wherein the another material includes the Group IB material and the Group IIIA material, and the step of electrodepositing deposits a Group VAIBIIIA thin film on the conductive surface.

14. The method of claim 13 wherein the Group VA material includes Sb.

15. The method of claim 13 wherein the Group VA material includes Bi.

16. The method of claim 13 wherein the Group VA material includes Sb.

17. The method of claim 11 wherein the another material includes the Group IB material, the Group IIIA material species and the Group VIA material, and the step of electrodepositing deposits a Group VAIBIIIAVIA thin film on the conductive surface.

18. The method of claim 17 wherein the Group VA material includes Sb.

19. The method of claim 17 wherein the Group VA material includes Bi.

20. The method of claim 17 wherein the Group VA material includes Sb.
